(19) United States
(12) Patent Application Publication
(10) Pub. No.: US 2003/0070612 A1
(43) Pub. Date: Apr. 17, 2003

(54) Vented susceptor

(76) Inventor: Kennard K. Addis, Washougal, WA (US)

Correspondence Address: Douglas G. Anderson, P.O. Box 8965, Vancouver, WA, 98668-8965, US

(21) Appl. No.: 09/976,796

(22) Filed: Oct. 12, 2001

(51) Int. Cl. C30B 15/00; C30B 21/06; C30B 27/02; C30B 28/10; C30B 30/04

(52) U.S. Cl. 117/213

(57) ABSTRACT

A susceptor for use in a Czochralski crystal growing apparatus is disclosed wherein erosion of the susceptor is minimized. The susceptor contains ventilation holes that allow process gases found between the susceptor and crucible to escape. The crucible may incorporate the use of a protective coating over part or all of the susceptor, such as a silicon carbide coating. The ventilation holes are placed at various heights along the susceptor wall to allow ventilation near the area of plastic deformation of the crucible.

### FIELD OF THE INVENTION

The present invention relates to a graphite susceptor used to form semiconductor ingots, and particularly to a susceptor that contains ventilation holes.

### BACKGROUND OF THE INVENTION

One common method for producing monocrystalline semiconductor ingots used to manufacture semiconductor wafers is the so-called Czochralksi (CZ) method. When growing an ingot using the Czochralski method, charge material such as silicon, gallium-arsenide, and the like, is loaded into a generally bowl-shaped crucible. The crucible is typically made out of quartz, and is supported and surrounded by a susceptor, typically made out of graphite or graphite composite. The susceptor typically is similarly shaped to the crucible, such that the general appearance is a bowl within a bowl. A circumferential heater surrounds the susceptor, and supplies heat to melt the charge material to a molten state. A seed crystal with the desired crystalline structure is then lowered into contact with the melt, and allowed to thermally stabilize. The seed is rotated in one direction, and the crucible is rotated in the opposite direction. The seed is then raised at a controlled rate, thus enabling growth of a crystal. Typically, crystal growth is accomplished at a pressure lower than atmospheric, with an inert purge gas supplied to flush the system of impurities.

During silicon crystal growth, temperatures are elevated to approximately 1425° C. This is sufficiently high to allow the quartz crucible to experience plastic deformation, wherein it is still capable of containing the molten silicon, but the circumferential area around the base expands and stretches. Often the crucible will stretch enough to come in contact with, and be supported by the susceptor.

The contact between the quartz crucible and the graphite susceptor at these elevated temperatures limits the useable lifetime of the susceptor. Silicon oxide (SiO) gas is emitted from the crucible during crystal growth, which causes a chemical reaction to occur with the graphite susceptor. Oxygen from the SiO gas erodes the graphite and forms carbon monoxide (CO) and carbon dioxide (CO₂). Silicon, on the other hand, combines with the graphite to form silicon carbide (SiC). Depending on the gas flow properties of the area, the gases can enhance erosion of the graphite susceptor, and shorten the useable lifetime even further.

Attempts have been made to control erosion of graphite parts, including the susceptor, with limited success and with high costs. For example, in U.S. Pat. No. 5,476,679, Lewis et al. discloses a method for coating a susceptor with a glassy carbon coating. Although this method is effective in reducing metallic contamination being introduced to the crucible, it has not been fully effective in protecting erosion.

Silicon Carbide coatings have also been employed in attempts to protect graphite parts and thereby increase useable lifetime. Unfortunately, the difference in thermal expansion coefficients of graphite and silicon carbide result in separation between the graphite and silicon carbide coating and cracking of the silicon carbide coating. Therefore, not only is coating with silicon carbide not fully functional, it is also quite expensive to apply, as it is typically applied by chemical vapor deposition techniques (CVD).

In co-pending U.S. patent application Ser. No. 09/553,818 Kondo et al. at least partially obviate the limitations of silicon carbide coating by silicon carbide implantation, wherein silicon carbide is introduced into the graphite itself, and then gradually increase the percentage of silicon carbide and reduce the percentage of graphite approaching the surface, to the point where the surface is entirely silicon carbide. This technique increases the peel strength over a silicon carbide layer, and allows for a thinner layer to be produced, thereby reducing costs of implementation. There remains erosion, albeit at a slower rate.

U.S. Pat. No. 6,221,478 (Kammeyer) discloses a method of putting a silicon carbide layer on the surface by a technique of applying a silicon-containing paste to a selected surface area of a graphite part. The silicon containing paste contains silicon containing powder and carbon containing liquid. The paste is applied to the desired areas, and is then heated so that the silicon in the paste melts and reacts with carbon on the surface of the graphite component, converting the graphite to form a protective silicon carbide coating. This method also allows coating of desired areas only. Once again, however, there remains erosion.

Accordingly, there is a need for reduced erosion of graphite parts in general and susceptors in specific, including the need for enhanced gas flow properties.

### SUMMARY OF THE INVENTION

The present invention provides a susceptor that includes a plurality of vent holes cut into the side walls of the susceptor to facilitate improved gas flow characteristics. The vent holes are cut into the susceptor are placed such that they will not be obstructed by the plastic deformation of the crucible, such that if the crucible expands and comes in contact with the susceptor the vent holes will remain functional.

The apparatus of the present invention may be employed alone, or in conjunction with coating of silicon carbide or through chemical vapor implantation of silicon carbide.

### BRIEF DESCRIPTION OF THE DRAWINGS

FIG. 1 is a partial sectional view of a Czochralski crystal growing apparatus.

FIG. 2 is a partial sectional view of a crucible housed within a suspector before heating.

FIG. 3 is a partial sectional view of a crucible housed within a susceptor at elevated temperatures.

FIG. 4 is a sectional view of a susceptor containing vent holes.

### DETAILED DESCRIPTION OF THE INVENTION

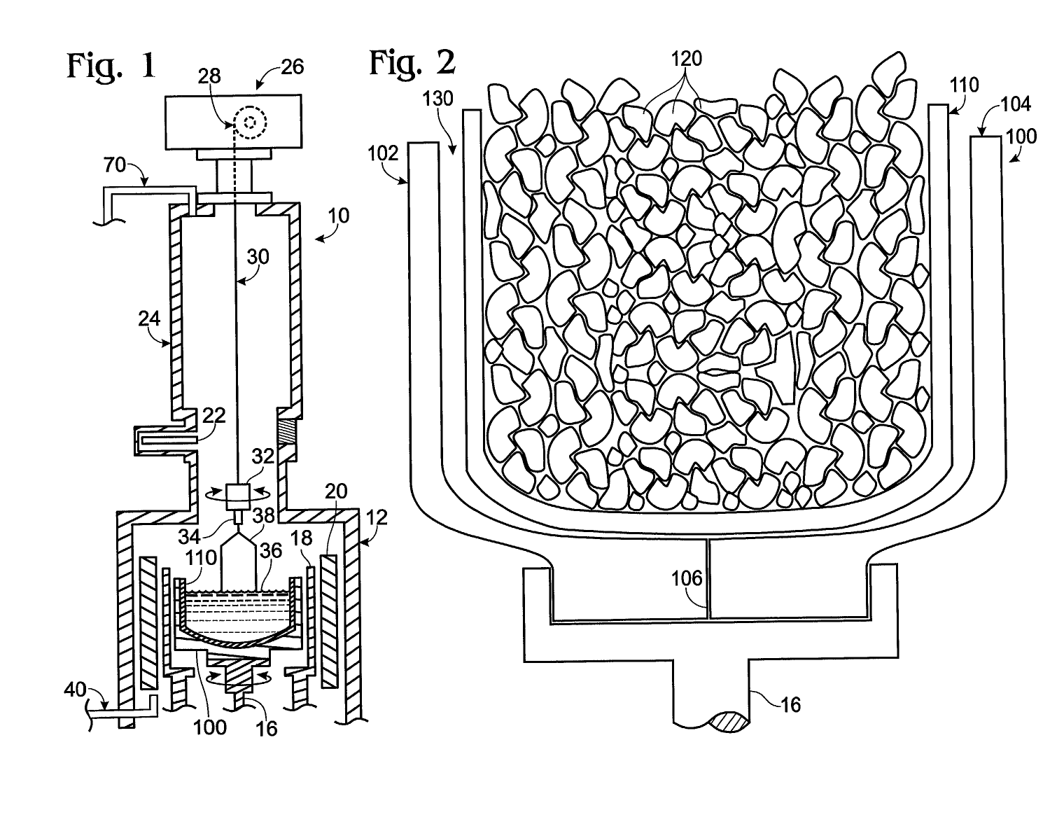

Turning now to FIG. 1, a crystal growing apparatus 10 includes a bottom chamber 12. The bottom chamber 12 houses a quartz crucible 110, which is supported by a susceptor 100. The susceptor 100 is in turn supported by a vertically moveable and rotatable shaft assembly 16. A cylindrical heater 18 made of, for example, graphite is disposed around the susceptor 100, which in turn is surrounded by and insulating cylinder 20. The bottom chamber 12 also has a conduit 40 for evacuating air during start up, and process gas during crystal pulling operations utilizing a vacuum pump (not shown).

A top chamber 24 is disposed above the bottom chamber 12 while an isolation valve 22 is disposed there between. The top chamber 24 provides a space for accommodating a grown crystal. The isolation valve 22 functions to allow a vacuum tight separation between the top chamber 24 and the bottom chamber 12 thus enabling a grown crystal to be removed from the top chamber 24 without losing vacuum or temperature in the bottom chamber 12. The top chamber 24 has a conduit 70 that goes to a vacuum pump (not shown) that allows the top chamber to be evacuated of air and purge gases, so it may be rejoined with the bottom chamber 12. When the isolation valve 22 is opened, a purge gas such as argon is introduced through conduit 70, flowed through the entire growing apparatus 10, and exited through conduit 40.

A winding mechanism 26 is disposed above the top chamber 24, and includes a winding drum 28 within the winding mechanism 26. The winding mechanism 26 is rotatable around a vertical axis with respect to the top chamber 24. A wire 30 is wound onto the winding drum 28, and extends downward. A seed chuck 32 for holding a crystal seed 34 is attached to the lower end of the wire 30.

When a single crystal is to be grown in the crystal growing apparatus 10, the isolation valve 22 is in an open position so as to allow the seed 34 to be lowered into the bottom chamber 12. Both the bottom chamber 12 and the top chamber 24 are evacuated and purged of air, and an inert gas is then flowed through the apparatus for the remainder of the growing process. A charge material, such as silicon, is placed in the crucible 110, and heated by the heater 18, thereby making a molten material 36.

The seed crystal 34 is lowered by winding drum 28 until the end of the seed crystal 34 is lowered into the molten material 36. After allowing the seed crystal 34 to reach temperature equilibrium with the molten material 36, the winding drum 28 slowly begins to wind up the wire 30, thus enabling a crystal 38 to be pulled or grown. During the growing operation, the winding mechanism 26 and thus the seed are rotating in the opposite direction of the shaft assembly 16.

As previously mentioned, at the elevated temperatures during crystal growth the crucible and susceptor interact to form CO and CO₂ gases and SiC. The purge gas, typically argon, is used to assist in cooling the crystal and to flush out the CO, CO₂, and SiC from the growing chamber. Typical argon flow ranges from 120 to 190 cubic liters per minute during growth, and will be significantly higher during purging processes.

As shown in FIG. 2, susceptor 100 contains two mirror-image portions 102 and 104. An expansion gap 106 separates the two portion 102 and 104, and allows the portions 102 and 104 to expand and contract during heating and cooling without significantly changing the dimensions of the susceptor 100. The susceptor 100 is held together at the bottom by sitting it a cup located at the top of the rotatable shaft assembly 16. The quartz crucible 110 is housed within the susceptor 100, and is packed with charge material 120 that is to be melted and grown into a monocrystalline ingot. Before heat is supplied to melt the charge material 120, there is a gap between the wall of the crucible 110 and the susceptor 100. Purge gas 130 can flow downward between the walls of the crucible 110 and susceptor 100. The only exit for the purge gas 130 to escape is through the expansion gap 106 such that the gas flow between the walls of the crucible 110 and the susceptor 100 becomes turbulent, and changes from a laminar downward directed flow to a turbulent flow swirling between the walls until it encounters and escapes through the expansion gap 106.

FIG. 3 demonstrates the interaction of the susceptor 100 and the crucible 110 after sufficient heat has been supplied to change the charge material into a molten material 36. At an area located approximate to the surface of the molten material 36, the crucible wall plastically deforms and expands at 112. As a crystal is extracted from the molten material 36, the volume of the molten material 36 will decrease and the surface of the molten material 36 will move downward relative to the crucible wall 110 and the area of plastic deformation 112. After the crucible 110 plastically deforms at 112, however, it does not move downward to follow the relative position of the surface of the molten material 36, but rather remains at a constant position. Purge gas 130 flows downward between the walls of the crucible 110 and the susceptor 100 to the point of plastic deformation 112, and is turbulently forced out at the expansion gap 106. Due to the extreme heat and chemical reactions between the susceptor 100 and crucible 110 as previously explained, the area of plastic deformation 112 is subject to a much more aggressive erosion than other parts of the susceptor 100.

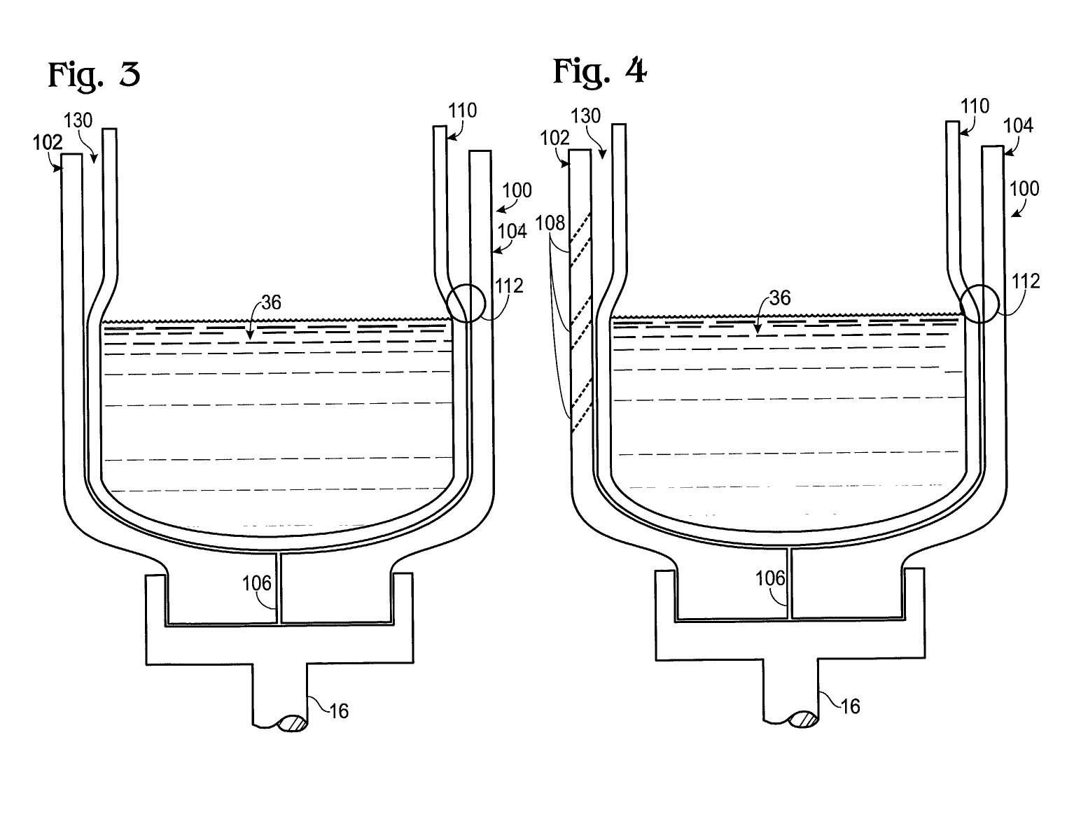

As shown in FIG. 4, to provide more escape passages for the purge gas 130, vent holes 108 are cut through the sidewall of the susceptor portions 102 and 104. Vent holes 108 can be cut at a downward angle from the inside out to help facilitate better gas flow properties and more laminar flow. The vent holes 108 can also be cut at numerous distances from the top of the susceptor to facilitate various melt surface levels such that at least some of the vent holes 108 will be near the area of plastic deformation 112, but will not be occluded by the wall of the crucible 100. In this situation, there may be some vent holes 108 that are occluded by the wall of the crucible 100, and others that are above the area of plastic deformation 112. The physical shape of the vent holes 108 should be manufactured to reasonably facilitate desired gas flow properties. The size and quantity of vent holes 108 should not be so large as to risk structural failure of the susceptor 110.

It should be noted that the present invention may be used on graphite susceptors alone, or in conjunction with other erosion inhibiting methods. For example, a susceptor containing vent holes made out of a carbon based material such as graphite may be completely covered with a silicon carbide coating. Another embodiment may utilize providing a protective coating such as silicon carbide in the area proximal to the vent holes and along the expansion gap. Yet another embodiment includes enhancing erosion resistance by chemical vapor implantation of a protective layer such as silicon carbide.

Although the invention has been described with reference to specific embodiments, other embodiments of the present invention will be apparent to those skilled in the art from a consideration of this specification or practice of the invention disclosed herein. It is intended that the written description be considered in all aspects only as illustrative and not restrictive. The scope of the invention is, therefore, indicated by the appended claims rather than by the foregoing description. All changes that come within the meaning and range of the equivalence of the claims are to be embraced within their scope.

What is claimed is:

1. An apparatus used in production of semiconductor ingots using the Czochralski method comprising:
a crucible suitable for containing a melt;
a bowl-shaped susceptor at least partially disposed around and supporting the crucible, wherein the susceptor has a plurality of ventilation holes allowing any gas introduced between the crucible and the susceptor to escape through the ventilation holes.

2. The apparatus according to claim 1 wherein the susceptor is a graphite susceptor.

3. The apparatus according to claim 1, wherein the susceptor contains a protective coating.

4. The apparatus according to claim 3, wherein the protective coating is a silicon carbide coating.

5. The apparatus according to claim 1, wherein at least a portion of the ventilation holes are spaced vertically along at least a portion of the susceptor.
